(19) United States
(12) Patent Application Publication
(10) Pub. No.: US 2014/0209444 A1
(43) Pub. Date: Jul. 31, 2014

(54) TOUCH PANEL

(71) Applicant: HENGHAO TECHNOLOGY CO., LTD., Taoyuan County (TW)

(72) Inventors: Chien-Wen Lai, New Taipei City (TW); Ming Chuan Chih, Taoyuan County (TW)

(73) Assignee: HENGHAO TECHNOLOGY CO. LTD, Taoyuan County (TW)

(21) Appl. No.: 13/759,325

(22) Filed: Feb. 5, 2013

(30) Foreign Application Priority Data
Jan. 31, 2013 (TW) 102103604

(51) Int. Cl. H03K 17/96

(52) U.S. Cl. CPC H03K 17/9618
USPC 200/600

(57) ABSTRACT

A touch panel includes first electrode lines disposed along a first axis on a transparent substrate, adjacent first electrodes being connected via a first conductive connecting element. The touch panel also includes second electrode lines disposed along a second axis on the transparent substrate, adjacent second electrodes being connected via a conductive bridge. The conductive bridge includes low-temperature conductive material.

### CROSS-REFERENCE TO RELATED APPLICATIONS

The entire contents of Taiwan Patent Application No. 102103604, filed on Jan. 31, 2013, from which this application claims priority, are incorporated herein by reference.

### BACKGROUND OF THE INVENTION

1. Field of the Invention

The present invention generally relates to a touch panel, and more particularly to a touch panel with bridges comprised of low-temperature conductive material.

2. Description of Related Art

A touch screen is an input/output device that adopts sensing technology and display technology, and has been widely employed in electronic devices such as portable or hand-held electronic devices.

A capacitor-based touch panel is a commonly used touch panel that utilizes capacitive coupling effect to detect touch position. Specifically, capacitance corresponding to the touch position changes and is thus detected, when a finger touches a surface of the touch panel.

A touch panel is composed of X electrode lines and Y electrode lines, one kind of which is electrically connected via bridges. The bridges of conventional touch panels may commonly be made of metal. The metal bridges, however, suffer reflection and low light-transmittance. The bridges of conventional touch panels may be made of indium tin oxide (ITO). However, the formation of ITO requires high-temperature (e.g., greater than 300° C.) process environment accompanied with annealing process. Moreover, patterning the bridges requires strong acid such as Aqua regia (or royal water), which may probably damage the electrodes.

A need has thus arisen to propose a novel touch panel to overcome deficiencies of the conventional touch panels.

### SUMMARY OF THE INVENTION

In view of the foregoing, it is an object of the embodiment of the present invention to provide a touch panel with bridges comprised of low-temperature conductive material to simplify process, enhance touch sensitivity, and prevent reflection and low light-transmittance.

According to one embodiment, a touch panel includes a transparent substrate, first electrode lines, first conductive connecting elements, second electrode lines, conductive bridges and insulating blocks. The first electrode lines are formed along a first axis on the transparent substrate, the first electrode line includes plural first electrodes, and each first conductive connecting element is electrically connecting adjacent first electrodes along the first axis. The second electrode lines are formed along a second axis on the transparent substrate, the second electrode line includes plural second electrodes, and each conductive bridge has two ends respectively connecting adjacent second electrodes along the second axis, the conductive bridges including low-temperature conductive material. Each insulating blocks is disposed between the conductive bridge and the first conductive connecting element.

### BRIEF DESCRIPTION OF THE DRAWINGS

FIG. 1A to FIG. 1C show top views illustrative of manufacturing a touch panel according to one embodiment of the present invention;

FIG. 2 shows a cross-sectional view along a section line 2-2′ of FIG. 1C; and

FIG. 3 shows a cross-sectional view of a touch panel according to another embodiment of the present invention.

### DETAILED DESCRIPTION OF THE INVENTION

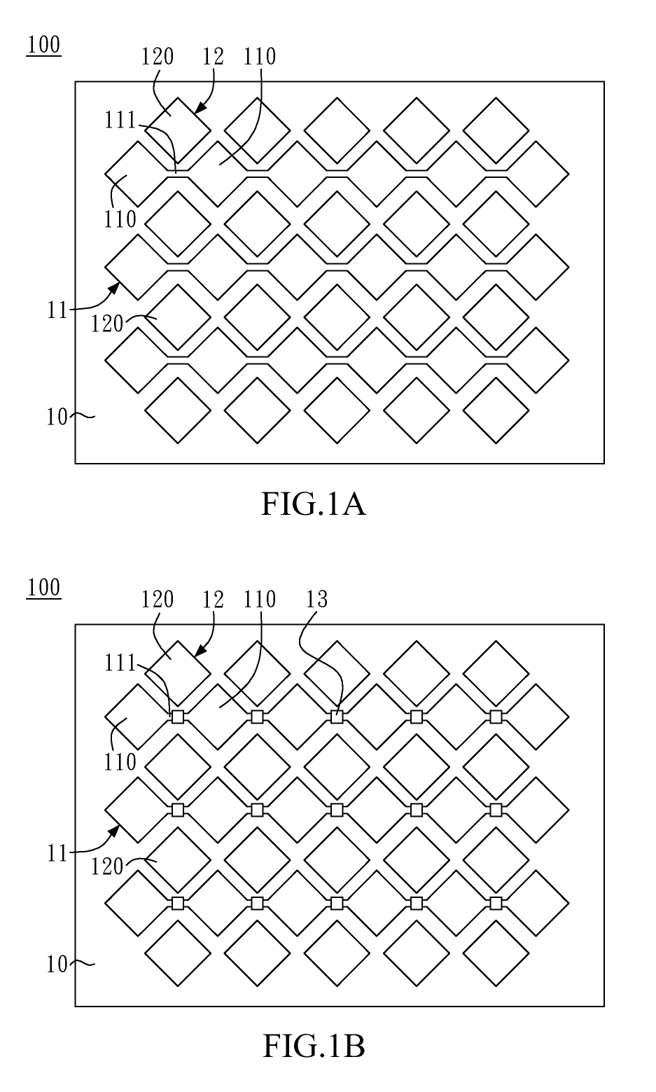

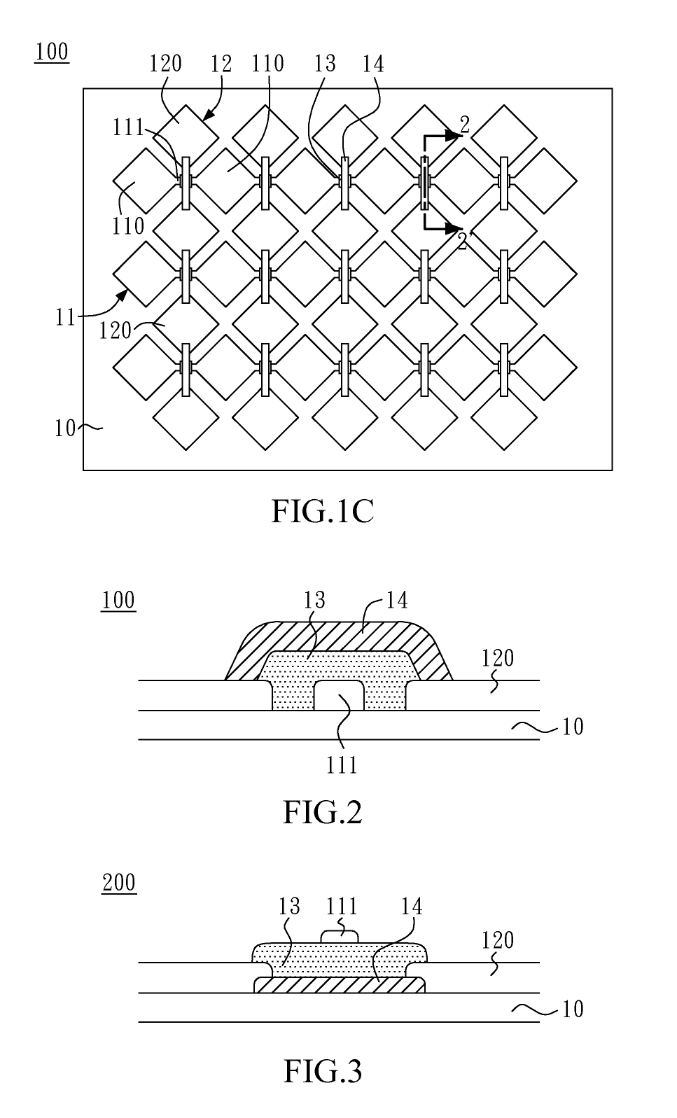

FIG. 1A to FIG. 1C show top views illustrative of manufacturing a touch panel 100 according to one embodiment of the present invention. FIG. 2 shows a cross-sectional view along a section line 2-2′ of FIG. 1C. The process flow illustrated in FIG. 1A to FIG. 1C is one of many processes to manufacture touch panels, and the present invention is not limited by the illustrated process.

As shown in FIG. 1A, first electrode lines 11 and second electrode lines 12 are formed on a transparent substrate 10. The first electrode lines 11 are disposed along a first axis, and the second electrode lines 12 are disposed along a second axis. The first electrode lines 11 are substantially parallel to each other, and the second electrode lines 12 are substantially parallel to each other. The first electrode lines 11 may, but not necessarily, be substantially perpendicular to the second electrode lines 12. The first electrode line 11 includes plural first electrodes 110, and the second electrode line 12 includes plural second electrodes 120. As shown in FIG. 1A, the second electrodes 120 are separated from each other, and adjacent first electrodes 110 along the first axis are connected via first conductive connecting elements 111. The first electrodes 110 and the second electrodes 120 may be designed to a shape other than the rhombus shape as exemplified in FIG. 1A.

The transparent substrate 10 may include insulating material such as glass, Polycarbonate (PC), Polyethylene terephthalate (PET), Polyethylen (PE), Poly vinyl chloride (PVC), Poly propylene (PP), Poly styrene (PS), Polymethyl methacrylate (PMMA) or Cyclic olefin copolymer (COC).

The first electrode line 11 and the second electrode line 12 may include a light-transmissive structure made of a non-transparent material. The non-transparent material may include metal nanowires (e.g., silver nanowires or copper nanowires) or metal nanonets (e.g., silver nanonets or copper nanonets). The metal nanowires or nanonets have a diameter in a nanometer order (i.e., a few nanometers to hundreds nanometers), and may be fixed in the first electrode line 11 and the second electrode line 12 via a plastic material (e.g., resin). Due to fineness of the metal nanowires/nanonets unobservable to human eyes, the first electrode line 11 and the second electrode line 12 made of the metal nanowires/nanonets thus have high light-transmittance. The first electrode line 11 and the second electrode line 12 may further include a photosensitive material (e.g., acrylic), through which electrodes with a required pattern may be formed via an exposure development process.

In another embodiment, the first electrode line 11 and the second electrode line 12 may include a light-transmissive structure made of a transparent material. The transparent material may include indium tin oxide (ITO), indium zinc oxide (IZO), Al-doped ZnO (AZO) or antimony tin oxide (ATO).

Subsequently, as shown in FIG. 1B, insulating blocks 13 are respectively formed on the first conductive connecting elements 111. The insulating block 13 may have a quadrilateral shape. The insulating blocks 13 may include optically clear adhesive (OCA) or silicon dioxide. The insulating blocks 13 may further include a photosensitive material (e.g., acrylic), through which a required pattern may be formed via an exposure development process.

Finally, as shown in FIG. 1C, a conductive bridge 14 is formed on the insulating block 13, and traces (not shown) are formed on periphery of the transparent substrate 10. A center of the conductive bridge 14 is disposed on the insulating block 13, and two ends of the conductive bridge 14 are respectively connected with adjacent second electrodes 120 along the second axis, therefore electrically connecting the second electrodes 120 of the same column. Further, the first electrode lines 11 and the second electrode lines 12 are electrically insulated from each other by the insulating blocks 13.

According to one aspect of the embodiment, the conductive bridge 14 may include low-temperature conductive material. In the embodiment, “low-temperature” may refer to room-temperature. Accordingly, low-temperature sputtering may be adopted to form a low-temperature conductive material layer without annealing. Compared with high-temperature conductive material (e.g., ITO) employed in conventional art to form bridges that require high-temperature (e.g., greater than 300° C.) process environment and annealing process, the embodiment thus has a simplified process overall. In a preferred embodiment, the low-temperature conductive material of the embodiment may include indium tin oxide (ITO) and zinc (Zn) (the combination of ITO and Zn may be called IXO), where zinc is 0.1-30% by weight.

Subsequently, the low-temperature conductive material layer is subjected to etching to form the conductive bridges 14. With respect to high-temperature conductive material (e.g., ITO) employed in conventional art to form bridges that require strong acid (e.g., Aqua regia or royal water) to result in required patterning, the strong acid may probably damage the electrodes. To the contrary, the low-temperature conductive material employed in the embodiment requires weak acid (e.g., Oxalic acid) to result in required patterning. It is noted that weak acid will not damage the first electrodes 110 and the second electrodes 120, therefore enhancing touch sensitivity of the touch panel 100. Moreover, as the embodiment adopts low-temperature conductive material as material of the conductive bridges 14, reflection and low light-transmittance problems suffered in the conventional touch panels with metal bridges can be prevented.

FIG. 3 shows a cross-sectional view of a touch panel 200 according to another embodiment of the present invention. Similar to the previous embodiment (FIG. 2), two ends of the conductive bridge 14 of the present embodiment are respectively connected with adjacent second electrodes 120 along the second axis, therefore electrically connecting the second electrodes 120 of the same column. Different from the previous embodiment (FIG. 2), the first conductive connecting element 111, the insulating block 13 and the conductive bridge 14 of the previous embodiment (FIG. 2) are stacked in order on the transparent substrate 10, while the conductive bridge 14, the insulating block 13 and the first conductive connecting element 111 of the present embodiment (FIG. 3) are stacked in order on the transparent substrate 10.

Although specific embodiments have been illustrated and described, it will be appreciated by those skilled in the art that various modifications may be made without departing from the scope of the present invention, which is intended to be limited solely by the appended claims.

What is claimed is:

1. A touch panel, comprising:
a transparent substrate;
a plurality of first electrode lines formed along a first axis on the transparent substrate, the first electrode line including a plurality of first electrodes;
a plurality of first conductive connecting elements, each of the first conductive connecting elements being electrically connecting adjacent first electrodes along the first axis;
a plurality of second electrode lines formed along a second axis on the transparent substrate, the second electrode line including a plurality of second electrodes;
a plurality of conductive bridges, each of the conductive bridges having two ends respectively connecting adjacent second electrodes along the second axis, the conductive bridges including low-temperature conductive material; and
a plurality of insulating blocks, each of the insulating blocks is disposed between the conductive bridge and the first conductive connecting element.

2. The touch panel of claim 1, wherein the low-temperature conductive material comprises indium tin oxide (ITO) and zinc (Zn).

3. The touch panel of claim 2, wherein zinc is 0.1-30% by weight.

4. The touch panel of claim 1, wherein the low-temperature is room-temperature.

5. The touch panel of claim 1, wherein the first conductive connecting element, the insulating block and the conductive bridge are stacked in order on the transparent substrate.

6. The touch panel of claim 1, wherein the conductive bridge, the insulating block and the first conductive connecting element are stacked in order on the transparent substrate.

7. The touch panel of claim 1, wherein the transparent substrate comprises glass, Polycarbonate (PC), Polyethylene terephthalate (PET), Polyethylen (PE), Poly vinyl chloride (PVC), Poly propylene (PP), Poly styrene (PS), Polymethyl methacrylate (PMMA) or Cyclic olefin copolymer (COC).

8. The touch panel of claim 1, wherein the first electrode line or the second electrode line comprises a light-transmissive structure made of a non-transparent material.

9. The touch panel of claim 8, wherein the non-transparent material comprises a plurality of metal nanowires or metal nanonets.

10. The touch panel of claim 1, wherein the first electrode line or the second electrode line comprises a light-transmissive structure made of a transparent material.

11. The touch panel of claim 10, wherein the transparent material comprises indium tin oxide (ITO), indium zinc oxide (IZO), Al-doped ZnO (AZO) or antimony tin oxide (ATO).

12. The touch panel of claim 1, wherein the insulating blocks comprise optically clear adhesive (OCA), silicon dioxide or acrylic.
